(19) United States
(12) Patent Application Publication
(10) Pub. No.: US 2023/0298971 A1
(43) Pub. Date: Sep. 21, 2023

(54) MICROELECTRONIC STRUCTURE INCLUDING CONDUCTIVE POLYMER IN TRENCHES OF A CORE SUBSTRATE, AND METHOD OF MAKING SAME

(71) Applicant: Intel Corporation, Santa Clara, CA (US)

(72) Inventors: Shayan Kaviani, Phoenix, AZ (US); Darko Grujicic, Chandler, AZ (US); Suddhasattwa Nad, Chandler, AZ (US); Miranda Ngan, Chandler, AZ (US)

(73) Assignee: Intel Corporation, Santa Clara, CA (US)

(21) Appl. No.: 17/699,031

(22) Filed: Mar. 18, 2022

(51) Int. Cl. H01L 23/48; H01L 23/498; H01L 23/14; H01L 21/48; H01L 23/00; H01L 25/065

(52) U.S. Cl. CPC H01L 23/481; H01L 23/49816; H01L 23/49827; H01L 23/145; H01L 21/486; H01L 24/16; H01L 25/0652; H01L 2224/16225; H01L 2224/16145

(57) ABSTRACT

A microelectronic structure and a method of forming same. The microelectronic structure includes: a core substrate including one of a glass material or an organic material, and defining a plurality of trenches therein; electrically conductive vias extending within the trenches, the vias to provide electrical coupling through the core substrate to semiconductor packages to be attached to the core substrate, individual ones of the vias including: a trench liner adjacent walls of a corresponding one of the plurality of trenches, the trench liner including an electrically conductive polymer material having double carbon bonds; and a metal structure on the trench liner.

### TECHNICAL FIELD

This disclosure relates generally to deposition in trenches defined within a core substrate of a microelectronic structure.

### BACKGROUND

Core substrates used in microelectronic assemblies, whether active or passive, such as core substrates including glass or organic materials, are typically provided with high aspect ratio core trenches (hereinafter CTs) for the formation of electrically conductive core vias. To perform electroplating in through CTs, which may include silicon vias (TSVs) or through glass vias (TGVs), a thin layer of conductive material, such as Cu, may be sputtered on surfaces or walls of the CTs. Sputtering, in the state of the art, allows the conformal deposition of a conductive trench liner on walls of high aspect ratio CTs. The trench liner may for example include at titanium, chromium, and nickel, which may be sputtered with copper or alone. The trench liner may include one or more sputtered layers identified by distinct sputtered materials. The trench liner may then be used for metal plating of a conductive material thereon. Prior to metal deposition, if the CTs are for the formation of TGVs, they may undergo a pretreatment process of preparing a pretreated glass substrate by forming an organic-inorganic composite primer layer containing a nanoparticle with an amine-group on a surface of the glass substrate where the CTs are formed. The pretreatment process may be followed by a plating process of plating a metal layer on the pretreated glass substrate which is pretreated.

In order to provide the trench liner, the state of the art further sometimes uses precursors (metals and noble metals) that are not only typically expensive, but which can result in low throughput, and which is not practical for use with high aspect ratio CTs.

### BRIEF DESCRIPTION OF THE DRAWINGS

The embodiments of the disclosure will be understood more fully from the detailed description given below

and from the accompanying drawings of various embodiments of the disclosure, which, however, should not be taken to limit the disclosure to the specific embodiments, but are for explanation and understanding only.

FIG. 1A is a cross section of a microelectronic assembly in the form of a packaging substrate according to an embodiment of the present disclosure.

FIG. 1B is a cross sectional view of a core substrate with core vias therein.

FIG. 1C is a cross sectional view of the core substrate of FIG. 1B, with a conformal trench liner thereon deposited according to some embodiments.

FIG. 1D is a cross-sectional view of the core substrate of FIG. 1C, with the trench liner thereon after patterning.

FIG. 1E is cross sectional view of the structure of FIG. 1C, showing conductive material having been provided on the trench liner to provide metal structures through the core substrate according to some embodiments.

FIG. 2 is a cross-sectional side view of an integrated circuit device assembly that may include a MCP in accordance with any of the embodiments disclosed herein.

FIG. 3 is a block diagram of an example electrical device that may include a MCP assembly, in accordance with any of the embodiments disclosed herein.

FIG. 4 is a flow chart of a process according to some embodiments.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

Some embodiments provide a method of providing a trench liner in core vias of a core substrate to be used in a microelectronic structure. According to embodiments, the method includes deposition of an electrically conductive polymer material, such as thiophene based polymers by way of example, to act as a conductive seed layer on core vias (CTs) for electroplating, on trench walls of a trenches defined in a core substrate. Controlled thin-film deposition of an electrically conductive polymer material, may be enabled according to some embodiments by vacuum vapor deposition techniques, such as oxidative chemical vapor deposition (oCVD), by atomic layer deposition (ALD), or by chemical vapor deposition (such as CVD).

Some embodiments pertain to a microelectronic structure obtained from employing any of the methods of embodiments, where an electrically conductive polymer material is disposed adjacent walls of core vias within a core substrate, such as a core substrate including glass, silicon, or an organic or inorganic material, and where a conductive layer such as one including copper is then plated on the trench liner to provide electrically conductive vias extending through the core substrate.

Advantageously, embodiments provide a microelectronic structure with high aspect ratio vias formed within CTs (e.g. CTs being high aspect ratio CTs if they have a width to depth ratio of 1 on the one hand to 4 or more on the other hand (1:4 or smaller)), where an electrically conductive polymer material may be disposed on walls of CTs thereof, and an electrically conductive layer may be disposed on the electrically conductive polymer material in order to create electrically conductive vias therewith.

In addition, where the electrically conductive polymer is deposited using vacuum vapor deposition methods, such as oCVD provides several additional advantages may be observed. For example, oCVD provides a reliable method of controlling thin-film deposition of an electrically conductive polymer material (with a thickness for example in the range of less than about 10 nm to about one micron) on a surface, including stable adhesion of such materials. In addition, deposition rates using oCVD deposition rate are significantly faster as compared with ALD and physical vapor deposition (PVD) techniques, leading to higher throughput for some embodiments. Moreover, oCVD reactants, including monomers and oxidants typically use in oCVD, are made of abundant and cost-effective elements. Furthermore, electrically conductive polymer materials provide surfaces that are suitable for metal electroplating in order to achieve electrically conductive vias extending through the CTs of a core substrate.

In addition, advantageously, vacuum vapor deposition allows a more ready control of a deposited trench liner layer (more accurate deposition rate) than do other deposition methods such as CVD, and much better step coverage than provided by sputtering of the trench liner layer, in certain embodiments allowing the resulting structure to be taken for electroplating without any intermediate procedures. CVD on the other hand may be performed to yield higher deposition rates than ALD.

Moreover, advantageously, polymers provide much better stress relief, because of their relative pliability as compared with metals. Such stress relief is to be considered for example where there is a coefficient of thermal expansion (CTE) mismatch between the material of the core substrate 104 (e.g. glass or organic) and that of the layers 109 and 115 above and below the core substrate 104. In such instances, the trench liner layer made of a conductive polymer can provide a mechanical buffer as between layers having differing CTEs. Polymers, as compared with metals or crystalline materials, are typically more flexible and can tolerate additional lateral stresses from the different layers adjacent the core substrate layer.

Additionally, advantageously, conductive polymers are typically less expensive than noble metals, and therefore provide a cost-effective and technically advantageous alternative to trench liner materials of the prior art.

By “core substrate” or “core,” what is meant herein is any supportive layer that is not electrically conductive, and that is to support microelectronic components thereon.

By “trench,” what is meant herein is any opening, whether blind or whether extending in a thickness direction of a semiconductor layer from one surface of the semiconductor layer to another surface of the layer.

By “electrically conductive via” or “via,” what is meant herein is any electrically conductive structure that has a largest dimension thereof extending at least partially through a semiconductor layer along a direction of a thickness of the semiconductor layer, the via being in a “trench” as defined herein. Thus, as used herein, a via may extend through a semiconductor layer, or simply extend across the same without connecting end surfaces thereof.

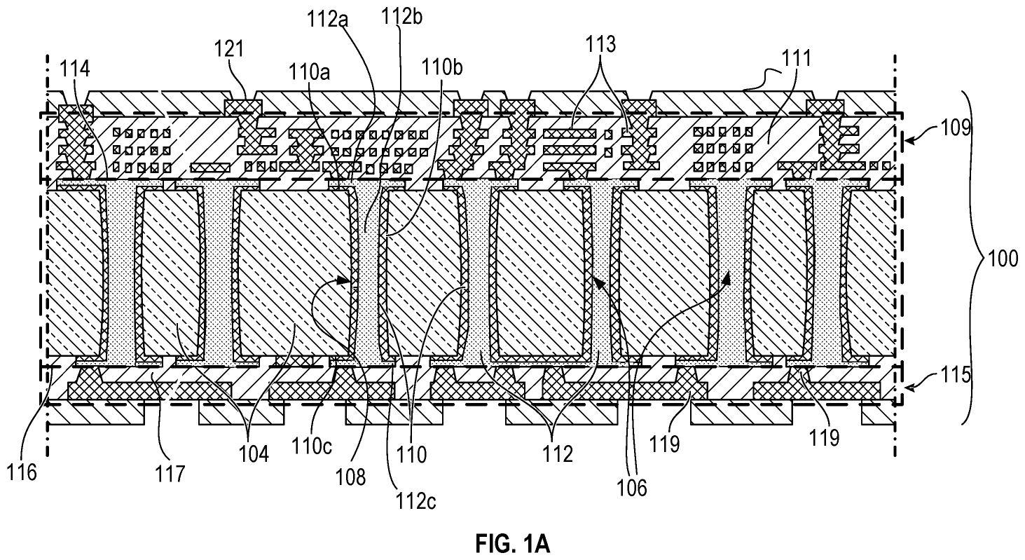

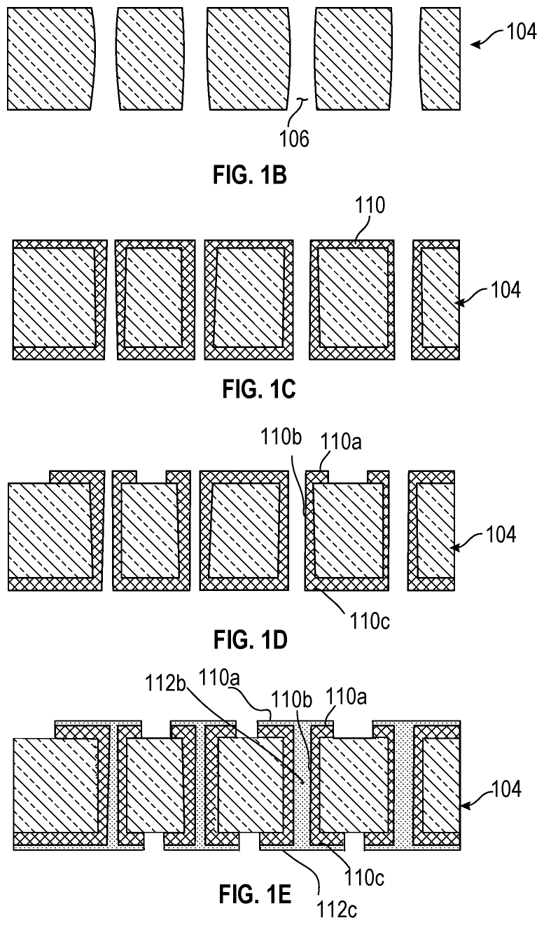

Details of some embodiments will be described in further detail in relation to FIGS. 1A-1E below, after general remarks, in the immediate next few paragraphs, regarding the scope of the disclosure.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the instant detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

An explanation will now follow below regarding embodiments in the context of FIGS. 1A, 1B, 1C, and 1D. FIG. 1A shows a microelectronic structure including a semiconductor package according to an embodiment FIGS. 1B-1E together show various stages of a process flow for providing an electrically conductive polymer seed layer on core vias of a core substrate according to an embodiment. As between FIGS. 1A-1E, like components are indicated using like reference numerals, and, therefore, a description of such components may not be provided again in the context of FIGS. 1A-1E.

Referring to FIG. 1A, a microelectronic structure 100 is shown in the form of a semiconductor package. Microelectronic structure 100 includes a core layer 102 which comprises a core substrate 104 perforated with core trenches 106, the core trenches 106 having electrically conductive vias 108 (“vias”) therein. The core layer 102 supports at an upper surface 114 thereof, an upper distribution layer 109, which may include an electrically insulating material 111 and electrically conductive redistribution structures 113 embedded therein. The core layer 102 includes, at a lower surface 116 thereof, a lower distribution layer 115, which may include an electrically insulating material 117 and electrically conductive redistribution structures 119 embedded therein.

The core substrate 104 according to some embodiments may include glass, or an organic material. Where the core substrate includes a glass material, it may, for example, include borosilicate glass, non-alkali glass, or the like. Where the core substrate includes an organic material, it may, for example, include a high-density organic substrate such as a high-density package (HDP) substrate or the like. Where the core substrate is a glass core substrate, it may have a thickness of about 1,000 μm or less, for example a thickness of about 100 to about 1,000 μm, or a thickness from about 100 to about 700 μm. The glass substrate 104 may have a thickness of 100 to 500 μm.

Referring still to FIG. 1A, the vias 108 include a trench liner (which may serve as a core seed layer) 110, and an metal structure 112 thereon. Vias 108 provide an electrical coupling between one side 114 of the core layer 102 and an opposite side 116 of the core layer 102. Trench liner 110 covers walls of the trenches 106 at trench portions 110b thereof, and further extends above and below the walls of the trenches respectively at surface signal portions 110a and 110c thereof. The metal structure 112 may include trench portions 112b on the trench portions 110b of the trench liner 110, and further extends above and below the trenches with surface signal portions 112a and 112c on surface signal portions 110a and 110c of the trench liner 110, respectively. The trench liner 110 may include an electrically conductive polymer material. The configuration of the vias 108 allows the electrical coupling between active components attached to the bottom side 116 and to the top side 114 of the core layer 102. The vias 108 serve as a passage for transmitting electrical signals, thereby facilitating seamless signal transmission between the top surface 114 and bottom surface 116 of the core layer 102.

In upper distribution layer 109, the electrically insulating layer 111 may include, for example, a dielectric material, an epoxy-based resin comprising a filler, or any other electrically insulating material as would be within the knowledge of a skilled person. Redistribution structures 113 may define a pattern to route signals to and from the vias 108, the pattern embedded within the insulating material of layer 111. The upper distribution layer 109 may be provided for using a build-up processes, using deposition of the insulating material, patterning the insulating material, and providing electrically conductive material onto the insulating material in a predetermined pattern, such as through plating, patterning the electrically conductive material, and repeating this process until the distribution layer is formed. Electrically conductive pads 121 may be provided to establish electrical coupling with the redistribution structures 113, and may, for example, be coupled to one or more dies to be supported on the microelectronic structure 100, either directly, for example via hybrid bonding, or indirectly, for example through solder balls or other electrically conductive structures.

Similar to the upper distribution layer 109, in lower distribution layer 115, the electrically insulating layer 117 may include, for example, a dielectric material, an epoxy-based resin comprising a filler, or any other electrically insulating material as would be within the knowledge of a skilled person. Redistribution structures 119 may define a pattern to route signals to and from the vias 108, the pattern embedded within the insulating material of layer 117. The lower distribution layer 115 may be provided for using a build-up processes, using deposition of the insulating material, patterning the insulating material, and providing electrically conductive material onto the insulating material in a predetermined pattern, such as through plating, patterning the electrically conductive material, and repeating this process until the distribution layer is formed. Redistribution structures 119 may be used establish electrical coupling with, for example, a motherboard, or with one or more dies to be supported on the microelectronic structure 100, using any coupling method, such as solder balls, hybrid bonding, and the like.

In layers 109 and 115, redistribution structures 113 and 119 may include any configuration of an electrically conductive structure, such as, by way of example, traces, lines, pads, vias, via pads, holes, and/or planes.

FIGS. 1B to 1E show various stages in a process for forming a core layer similar to core layer 102. Although the structures shown in FIG. 1B to 1E may not match the core layer 102 exactly, it is to be understood that the process described in the context of FIGS. 1B to 1E is applicable to the formation of core layer 102 of FIG. 1, and should therefore be interpreted accordingly.

Referring to FIG. 1B, the core substrate 104 of FIG. 1A is shown after the provision of core trenches 106 therein. The trenches may be provided according to any method as would be within the knowledge of a skilled person, such as, for example, by way of etching, such as mechanical and/or chemical etching, and/or laser drilling. For example, with chemical etching, a wet etch involving use of hydrofluoric acid and/or nitric acid, may be used.

FIG. 1C is a cross sectional view showing the core substrate 104 of FIG. 1B having been provided with the trench liner 110. The trench liner may have a thickness of less than 10 nm up to about a micron. The trench liner 110 may include a conductive polymer that has a conjugated backbone including double-carbon bonds alternating with single carbon bonds. The conductive polymer material may include conjugated pi bonds.

Conjugated electrically conductive/conducting polymers are pi-conjugated (or π-conjugated) organic molecules or polymers with alternating single and double bonds, such as alternating single and double carbon bonds (C—C alternating with C═C). Alternating single and double bonds create a conjugated pi bond system across multiple atoms that lowers the energy and stabilizes the molecule or ion. The delocalized π electrons create a halo of electronic density above and beyond the molecular plane, which provides the pathway for electrons to move alongside the material, and this phenomena makes the polymer conductive. Validation of the presence of C═C bonds in the backbone structure of the deposited polymer material confirms both organic nature and conductive properties of the material.

Characterization of the double C bonds may be performed using various techniques, such as: Fourier Transform Infra-Red (FTIR) spectroscopy, Raman Spectroscopy and X-ray photoelectron spectroscopy (XPS) to name a few. Raman and FTIR spectroscopies could further be used to detect an exact fingerprint of the deposited material. Other characterization techniques such as Variable Angle Spectroscopic Ellipsometry (VASE), Scanning Electron Microscopy (SEM) and Atomic Force Microscopy (AFM) could be used to detect the thickness of the deposited material and Energy Dispersive X-ray Spectroscopy (EDX) and XPS could be used for further elemental analysis and stoichiometric calculations.

The vapor deposition of electrically conductive polymers, such as thiophene based polymers, can lead to a thin layer (sub 10 nm to a micron) that acts as conductive layer on walls of via trenches for subsequent electroplating.

In sub-10 nm thicknesses of the trench liner layers, VASE, FTIR, Raman spectroscopy, AFM, Atomic Force Infra-Red Microscopy (AFM-IR), and XPS could detect the deposition of thin films. For higher deposition thicknesses, in addition to the mentioned techniques X-SEM and X-EDS can detect the material.

According to some embodiments, the electrically conductive polymer may a conductivity of up to 10000 S/cm, or it may have an even higher conductivity.

OCVD enables oxidative polymerization using any of a variety of starting monomers and a vaporizable oxidant initiator which acts as an electron acceptor chemical to complete the polymerization reaction on the surface of the substrate (monomer).

Starting monomers for electrically conductive polymers may include, by way of example, at least one carbon, nitrogen, oxygen, sulfur and hydrogen.

For example, a list of possible monomers for thin film deposition of conjugated polymers according to some embodiments include one or more of the following chemicals: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), Dopamine (DA), 3,4-Propylene dioxythiophene (ProDOT), 3,4-(2,2-Dimethylpropylenedioxy)thiophene (DMProDOT), 2,2′-Bithiophene (BiT)3,2′:5′,3″-Terthiophene (TerT), Thieno[3,2-b]thiophene (TT).

Electron acceptor chemicals may be selected among Lewis acids, such as FeCl₃, SbCl₅, or VOCl₃. The electron acceptor chemical reduces the monomer and, in this manner, leads to polymerization of the same at surfaces thereof.

The vacuum deposition technique according to some embodiments, for example oCVD, may preferably be carried out at a working pressure between about 100 and about 500 mTorr, and may further rely on continuous delivery of the reactants (monomer(s) and electron acceptor chemical(s). The vacuum deposition technique may occur at pressures above 500 mTorr. The noted temperature and pressure combination enables conformal and controlled deposition of material in tortuous and patterned substrates, for example a core including high aspect ratio trenches. Preferably, the oCVD process according to embodiments is to take place at room temperature and up to about 300 degrees Centigrade, for example within the pressure range of about 100 and about 500 mTorr or higher as noted above. The higher the substrate temperature, the higher the conformal deposition, keeping in mind however that a balance is to be achieved between higher temperatures and lower pressures according to some embodiments.

Vacuum vapor deposition causes a mean free path of electrons to be longer because of the vacuum (or low pressure) environment, in this manner allowing the reactants to diffuse through high aspect ratio trenches and conformally adhere to wall surfaces thereof.

Although the trench liner layer may be deposited in any suitable manner, for example using vapor depositions other than oCVD, such as PVD, or other deposition techniques, such as ALD, oCVD deposition rates can be significantly faster and more controllable s compared with ALD and PVD techniques. oCVD deposition rate is in the range of a few nanometers/min, while ALD deposition rate is in a range of a few Angstrom/min. oCVD further promotes conformal deposition and stable adhesion of conductive polymers on materials, including on glass materials.

Reference is now made to FIG. 1D, which shows the structure of FIG. 1C after patterning of the trench liner layer 110 has been patterned to provide trench liner signal portions 110a and 110c, and trench portions 110b as shown. The patterning of the trench liner may be performed according to any patterning method, such as, for example, by using a lithography and etch process. According to embodiments, it is not necessary that patterning of the trench liner layer 110 be performed immediately after its deposition, as it may occur at any time after deposition of the same, including after plating of an electrically conductive material thereon.

Referring now to FIG. 1E, the structure of FIG. 1D is shown after electroplating with an electrically conductive material, such as, for example, copper, and after patterning of the same to obtain metal structures 112b. Electroplating, and obtaining the metal structures 112b therefrom, may take place in any manner that is within the knowledge of a skilled person, such as, for example, by using electroplating followed by polishing. During plating, a thickness of an electrically conductive layer formed, may be controlled by regulating several variables such as the concentration of plating solution, plating time, and type of additive to be applied, as would be recognized by a skilled person.

Note that, while single layers are shown in FIGS. 1A-1E for each of the substrate, the barrier layer, the dielectric layer and the electrically conductive layer, it is to be appreciated that such layers may be made of multiple sublayers having differing compositions.

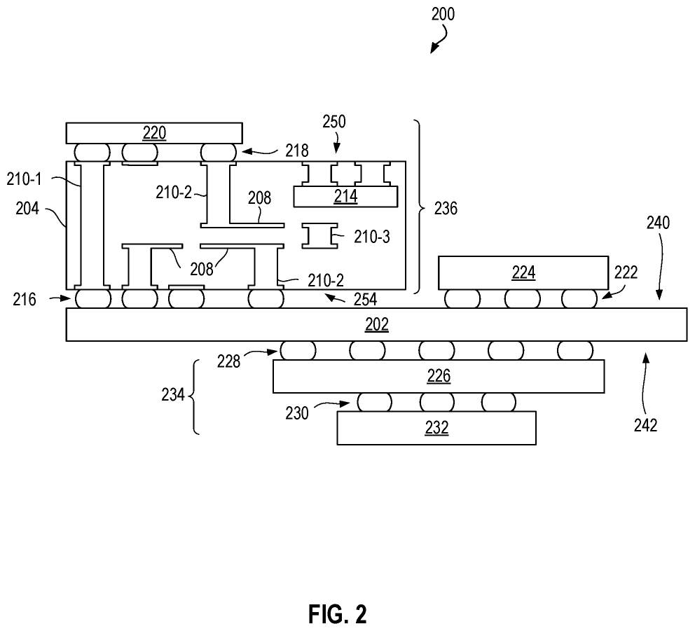

FIG. 2 is a cross-sectional side view of an integrated circuit device assembly 200 that may include one or more integrated circuit structures each including any of the microelectronic structure embodiments described herein (e. g. microelectronic structure 100 of FIG. 1E. The integrated circuit device assembly 200 includes a number of components disposed on a circuit board 202 (which may be a motherboard, system board, mainboard, etc.). The integrated circuit device assembly 200 includes components disposed on a first face 240 of the circuit board 202 and an opposing second face 242 of the circuit board 202; generally, components may be disposed on one or both faces 240 and 242. Any of the integrated circuit components discussed below with reference to the integrated circuit device assembly 200 may include an integrated circuit structure including a cascaded a MCP as disclosed herein.

In some embodiments, the circuit board 202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 202. In other embodiments, the circuit board 202 may be a non-PCB substrate. The integrated circuit device assembly 200 illustrated in FIG. 2 includes a package-on-interposer structure 236 coupled to the first face 240 of the circuit board 202 by coupling components 216. The coupling components 216 may electrically and mechanically couple the package-on-interposer structure 236 to the circuit board 202, and may include solder balls (as shown in FIG. 2), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 236 may include an integrated circuit component 220 coupled to an interposer 204 by coupling components 218. The coupling components 218 may take any suitable form for the application, such as the forms discussed above with reference to the coupling components 216. Although a single integrated circuit component 220 is shown in FIG. 2, multiple integrated circuit components may be coupled to the interposer 204; indeed, additional interposers may be coupled to the interposer 204. The interposer 204 may provide an intervening substrate used to bridge the circuit board 202 and the integrated circuit component 220.

The integrated circuit component 220 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 220, a single monolithic integrated circuit die comprises solder bumps attached to contacts on the die. The solder bumps allow the die to be directly attached to the interposer 204. The integrated circuit component 220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 204 may spread connections to a wider pitch or reroute a connection to a different connection. For example, the interposer 204 may couple the integrated circuit component 220 to a set of ball grid array (BGA) conductive contacts of the coupling components 216 for coupling to the circuit board 202. In the embodiment illustrated in FIG. 2, the integrated circuit component 220 and the circuit board 202 are attached to opposing sides of the interposer 204; in other embodiments, the integrated circuit component 220 and the circuit board 202 may be attached to a same side of the interposer 204. In some embodiments, three or more components may be interconnected by way of the interposer 204.

In some embodiments, the interposer 204 may be formed as a PCB, including multiple metal layers separated from one another by layers of dielectric material and interconnected by electrically conductive vias. In some embodiments, the interposer 204 may be formed of an epoxy resin, a fiberglass-reinforced epoxy resin, an epoxy resin with inorganic fillers, a ceramic material, or a polymer material such as polyimide. In some embodiments, the interposer 204 may be formed of alternate rigid or flexible materials that may include the same materials described above for use in a semiconductor substrate, such as silicon, germanium, and other group III-V and group IV materials. The interposer 204 may include metal interconnects 208 and vias 210, including but not limited to through hole vias 210-1 (that extend from a first face 250 of the interposer 204 to a second face 254 of the interposer 204), blind vias 210-2 (that extend from the first or second faces 250 or 254 of the interposer 204 to an internal metal layer), and buried vias 210-3 (that connect internal metal layers).

In some embodiments, the interposer 204 can comprise a silicon interposer. Through silicon vias (TSV) extending through the silicon interposer can connect connections on a first face of a silicon interposer to an opposing second face of the silicon interposer. In some embodiments, an interposer 204 comprising a silicon interposer can further comprise one or more routing layers to route connections on a first face of the interposer 204 to an opposing second face of the interposer 204.

The interposer 204 may further include embedded devices 214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 204. The package-on-interposer structure 236 may take the form of any of the package-on-interposer structures known in the art. In embodiments where the interposer is a non-printed circuit board

The integrated circuit device assembly 200 may include an integrated circuit component 224 coupled to the first face 240 of the circuit board 202 by coupling components 222. The coupling components 222 may take the form of any of the embodiments discussed above with reference to the coupling components 216, and the integrated circuit component 224 may take the form of any of the embodiments discussed above with reference to the integrated circuit component 220.

The integrated circuit device assembly 200 illustrated in FIG. 2 includes a package-on-package structure 234 coupled to the second face 242 of the circuit board 202 by coupling components 228. The package-on-package structure 234 may include an integrated circuit component 226 and an integrated circuit component 232 coupled together by coupling components 230 such that the integrated circuit component 226 is disposed between the circuit board 202 and the integrated circuit component 232. The coupling components 228 and 230 may take the form of any of the embodiments of the coupling components 216 discussed above, and the integrated circuit components 226 and 232 may take the form of any of the embodiments of the integrated circuit component 220 discussed above. The package-on-package structure 234 may be configured in accordance with any of the package-on-package structures known in the art.

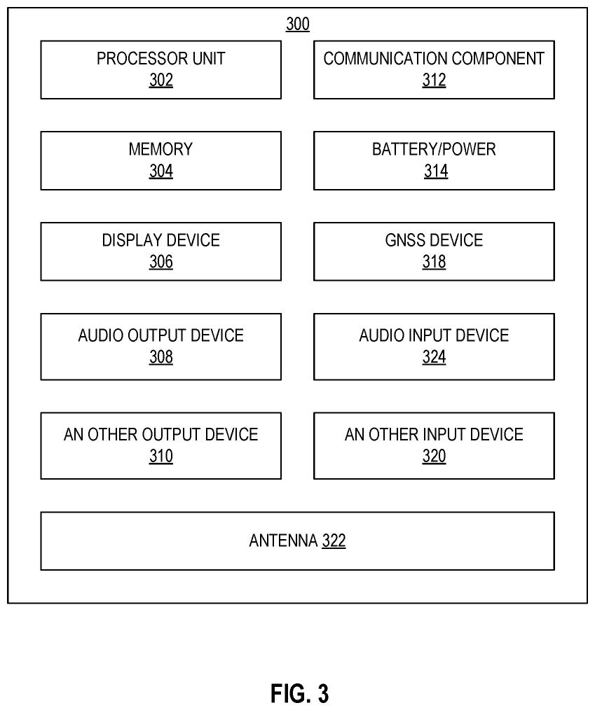

FIG. 3 is a block diagram of an example electrical device 300 that may include one or more of the embodiments of a microelectronic assembly disclosed herein. For example, any suitable ones of the components of the electrical device 300 may include one or more of the integrated circuit device assemblies 200, integrated circuit components 220, and/or embodiment MCPs disclosed herein. A number of components are illustrated in FIG. 3 as included in the electrical device 300, but any one or more of these components may be omitted or duplicated, as suitable for the application. In some embodiments, some or all of the components included in the electrical device 300 may be attached to one or more motherboards mainboards, or system boards. In some embodiments, one or more of these components are fabricated onto a single system-on-a-chip (SoC) die.

Additionally, in various embodiments, the electrical device 300 may not include one or more of the components illustrated in FIG. 3, but the electrical device 300 may include interface circuitry for coupling to the one or more components. For example, the electrical device 300 may not include a display device 306, but may include display device interface circuitry (e.g., a connector and driver circuitry) to which a display device 306 may be coupled. In another set of examples, the electrical device 300 may not include an audio input device 324 or an audio output device 308, but may include audio input or output device interface circuitry (e.g., connectors and supporting circuitry) to which an audio input device 324 or audio output device 308 may be coupled.

The electrical device 300 may include one or more processor units 302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 300 may include a memory 304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 304 may include memory that is located on the same integrated circuit die as the processor unit 302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 300 can comprise one or more processor units 302 that are heterogeneous or asymmetric to another processor unit 302 in the electrical device 300. There can be a variety of differences between the processing units 302 in a system in terms of a spectrum of metrics of merit including architectural, microarchitectural, thermal, power consumption characteristics, and the like. These differences can effectively manifest themselves as asymmetry and heterogeneity among the processor units 302 in the electrical device 300.

In some embodiments, the electrical device 300 may include a communication component 312 (e.g., one or more communication components). For example, the communication component 312 can manage wireless communications for the transfer of data to and from the electrical device 300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 312 may operate in accordance with other wireless protocols in other embodiments. The electrical device 300 may include one or more antennas, such as antenna 322 to facilitate wireless communications and/or to receive other wireless communications (such as AM or FM radio transmissions).

In some embodiments, the communication component 312 may manage wired communications, such as electrical, optical, or any other suitable communication protocols (e.g., IEEE 802.3 Ethernet standards). As noted above, the communication component 312 may include multiple communication components. For instance, a first communication component 312 may be dedicated to shorter-range wireless communications such as Wi-Fi or Bluetooth, and a second communication component 312 may be dedicated to longer-range wireless communications such as global positioning system (GPS), EDGE, GPRS, CDMA, WiMAX, LTE, EV-DO, or others. In some embodiments, a first communication component 312 may be dedicated to wireless communications, and a second communication component 312 may be dedicated to wired communications.

The electrical device 300 may include battery/power circuitry 314. The battery/power circuitry 314 may include one or more energy storage devices (e.g., batteries or capacitors) and/or circuitry for coupling components of the electrical device 300 to an energy source separate from the electrical device 300 (e.g., AC line power).

The electrical device 300 may include a display device 306 (or corresponding interface circuitry, as discussed above). The display device 306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 300 may include an audio output device 308 (or corresponding interface circuitry, as discussed above). The audio output device 308 may include any embedded or wired or wirelessly connected external device that generates an audible indicator, such speakers, headsets, or earbuds.

The electrical device 300 may include an audio input device 324 (or corresponding interface circuitry, as discussed above). The audio input device 324 may include any embedded or wired or wirelessly connected device that generates a signal representative of a sound, such as microphones, microphone arrays, or digital instruments (e.g., instruments having a musical instrument digital interface (MIDI) output). The electrical device 300 may include a Global Navigation Satellite System (GNSS) device 318 (or corresponding interface circuitry, as discussed above), such as a Global Positioning System (GPS) device. The GNSS device 318 may be in communication with a satellite-based system and may determine a geolocation of the electrical device 300 based on information received from one or more GNSS satellites, as known in the art.

The electrical device 300 may include another output device 310 (or corresponding interface circuitry, as discussed above). Examples of the other output device 310 may include an audio codec, a video codec, a printer, a wired or wireless transmitter for providing information to other devices, or an additional storage device.

The electrical device 300 may include another input device 320 (or corresponding interface circuitry, as discussed above). Examples of the other input device 320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 300 may be any other electronic device that processes data. In some embodiments, the electrical device 300 may comprise multiple discrete physical components. Given the range of devices that the electrical device 300 can be manifested as in various embodiments, in some embodiments, the electrical device 300 can be referred to as a computing device or a computing system.

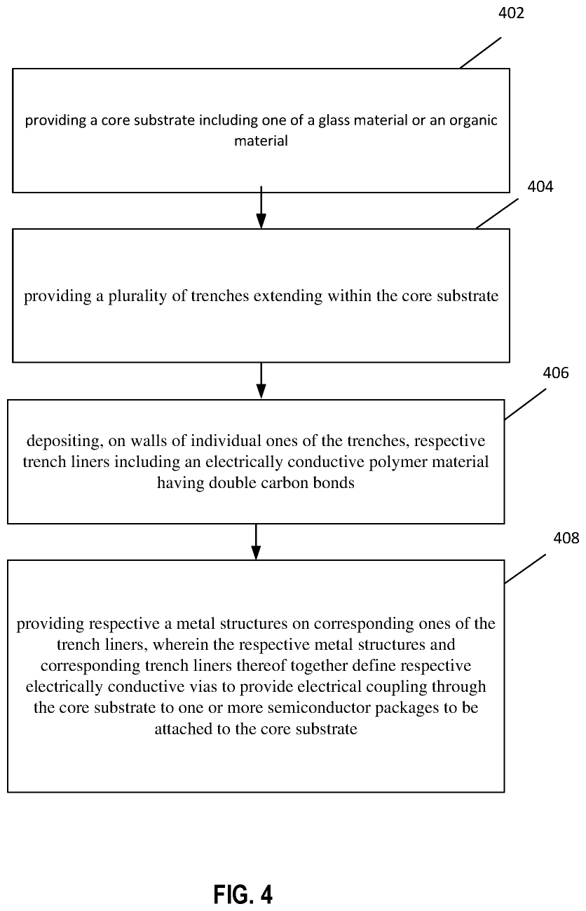

FIG. 4 is a flow chart of a process 400 of making a microelectronic assembly of a semiconductor package according to some embodiments. At operation 402, the process includes providing a core substrate including one of a glass material or an organic material. At operation 404, the process includes providing a plurality of trenches extending within the core substrate. At operation 406, the process includes depositing, on walls of individual ones of the trenches, respective trench liners including an electrically conductive polymer material having double carbon bonds. At operation 408, the process includes providing respective a metal structures on corresponding ones of the trench liners, wherein the respective metal structures and corresponding trench liners thereof together define respective electrically conductive vias to provide electrical coupling through the core substrate to one or more semiconductor packages to be attached to the core substrate.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

The use of reference numerals separated by a “/”, such as “102/104” for example, is intended to refer to 102 or 104 as appropriate. Otherwise, the forward slash (“/”) as used herein means “and/or.”

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one MCP including an interposer bonded to a MCP subassembly through direct dielectric-to-dielectric bonding as described herein.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

As used herein, an “integrated circuit structure” may include one or more microelectronic dies.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### Examples

Some non-limiting example embodiments are set forth below.

Example 1 includes a microelectronic structure, comprising: a core substrate including one of a glass material or an organic material, and defining a plurality of trenches therein; electrically conductive vias extending within the trenches, the vias to provide electrical coupling through the core substrate to semiconductor packages to be attached to the core substrate, individual ones of the vias including: a trench liner adjacent walls of a corresponding one of the plurality of trenches, the trench liner including an electrically conductive polymer material having double carbon bonds; and a metal structure on the trench liner.

Example 2 includes the subject matter of Example 1, wherein at least some of the vias are through vias extending across a thickness of the core substrate.

Example 3 includes the subject matter of Example 1, wherein the polymer material including single carbon bonds alternating with the double carbon bonds.

Example 4 includes the subject matter of Example 1, wherein the polymer material has an alkyl chain structure.

Example 5 includes the subject matter of Example 1, wherein the polymer material includes conjugated pi bonds.

Example 6 includes the subject matter of Example 1, wherein the polymer material further includes at least one of nitrogen, oxygen, sulfur or hydrogen.

Example 7 includes the subject matter of Example 1, wherein the polymer material is based on one or more monomers including at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT).

Example 8 includes the subject matter of Example 1, wherein the metal structure includes one or more layers including copper.

Example 9 includes the subject matter of Example 1, wherein, for individual ones of at least some of the electrically conductive vias, the metal structure fills openings defined by the trench liner.

Example 10 includes a semiconductor package including: a microelectronic structure, comprising: a core substrate including one of a glass material or an organic material, and defining a plurality of trenches therein; electrically conductive vias extending within the trenches, the vias to provide electrical coupling through the core substrate to semiconductor packages to be attached to the core substrate, individual ones of the vias including: a trench liner adjacent walls of a corresponding one of the plurality of trenches, the trench liner including an electrically conductive polymer material having double carbon bonds; and a metal structure on the trench liner; and microelectronic assemblies disposed on respective top and bottom surface of the core substrate and including dies electrically coupled to corresponding ones of the vias.

Example 11 includes the subject matter of Example 10, wherein at least some of the vias are through vias extending across a thickness of the core substrate.

Example 12 includes the subject matter of Example 10, wherein the polymer material including single carbon bonds alternating with the double carbon bonds.

Example 13 includes the subject matter of Example 10, wherein the polymer material has a conjugated backbone a conjugated backbone.

Example 14 includes the subject matter of Example 10, wherein the polymer material includes conjugated pi bonds.

Example 15 includes the subject matter of Example 10, wherein the polymer material further includes at least one of nitrogen, oxygen, sulfur or hydrogen.

Example 16 includes the subject matter of Example 10, wherein the polymer material is based on one or more monomers including at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT).

Example 17 includes the subject matter of Example 10, wherein the metal structure includes one or more layers including copper.

Example 18 includes the subject matter of Example 10, wherein, for individual ones of at least some of the electrically conductive vias, the metal structure fills openings defined by the trench liner.

Example 19 includes an integrated circuit (IC) device assembly including: a printed circuit board; and a plurality of integrated circuit components coupled to the printed circuit board, individual ones of the integrated circuit components including one or more semiconductor packages, individual ones of the semiconductor packages including: a microelectronic structure, comprising: a core substrate including one of a glass material or an organic material, and defining a plurality of trenches therein; electrically conductive vias extending within the trenches, the vias to provide electrical coupling through the core substrate to semiconductor packages to be attached to the core substrate, individual ones of the vias including: a trench liner adjacent walls of a corresponding one of the plurality of trenches, the trench liner including an electrically conductive polymer material having double carbon bonds; and a metal structure on the trench liner; and microelectronic assemblies disposed on respective top and bottom surface of the core substrate and including dies electrically coupled to corresponding ones of the vias.

Example 20 includes the subject matter of Example 19, wherein at least some of the vias are through vias extending across a thickness of the core substrate.

Example 21 includes the subject matter of Example 19, wherein the polymer material including single carbon bonds alternating with the double carbon bonds.

Example 22 includes the subject matter of Example 19, wherein the polymer material has a conjugated backbone.

Example 23 includes the subject matter of Example 19, wherein the polymer material includes conjugated pi bonds.

Example 24 includes the subject matter of Example 19, wherein the polymer material further includes at least one of nitrogen, oxygen, sulfur or hydrogen.

Example 25 includes the subject matter of Example 19, wherein the polymer material is based on one or more monomers including at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT).

Example 26 includes the subject matter of Example 19, wherein the metal structure includes one or more layers including copper.

Example 27 includes the subject matter of Example 19, wherein, for individual ones of at least some of the electrically conductive vias, the metal structure fills openings defined by the trench liner.

Example 28 includes a method to form a microelectronic structure of a semiconductor package, the method including: providing a core substrate including one of a glass material or an organic material; providing a plurality of trenches extending within the core substrate; depositing, on walls of individual ones of the trenches, respective trench liners including an electrically conductive polymer material having double carbon bonds; and providing respective a metal structures on corresponding ones of the trench liners, wherein the respective metal structures and corresponding trench liners thereof together define respective electrically conductive vias to provide electrical coupling through the core substrate to one or more semiconductor packages to be attached to the core substrate.

Example 29 includes the subject matter of Example 28, wherein depositing the trench liners includes using one of vacuum vapor deposition (VVD), atomic layer deposition (ALD) or physical vapor deposition (PVD).

Example 30 includes the subject matter of Example 29, wherein the VVD includes oxidative chemical vapor deposition (oCVD).

Example 31 includes the subject matter of Example 30, wherein the oCVD is to take place at a pressure between about 100 mTorr and about 500 mTorr.

Example 32 includes the subject matter of Example 30, wherein the oCVD is to take place at a temperature between room temperature (about 20 to about 22 degree Centigrade) and about 300 degrees Centigrade).

Example 33 includes the subject matter of Example 30, wherein the oCVD includes using reactants including one or more monomers, and one or more electron acceptor chemicals, wherein the one or more monomers include at least on of carbon, hydrogen, oxygen, sulfur or nitrogen, and wherein the one or more electron acceptor chemicals include a Lewis acid.

Example 34 includes the subject matter of Example 33, wherein the one or more monomers includes at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT).

Example 35 includes the subject matter of Example 28, wherein at least some of the vias are through vias extending across a thickness of the core substrate.

Example 36 includes the subject matter of Example 28, wherein the polymer material including single carbon bonds alternating with the double carbon bonds.

Example 37 includes the subject matter of Example 28, wherein the polymer material has a conjugated backbone.

Example 38 includes the subject matter of Example 28, wherein the polymer material includes conjugated pi bonds.

Example 39 includes the subject matter of Example 28, wherein the polymer material further includes at least one of nitrogen, oxygen, sulfur or hydrogen.

Example 40 includes the subject matter of Example 28, wherein the metal structure includes one or more layers including copper.

Example 41 includes the subject matter of Example 28, wherein, for individual ones of at least some of the electrically conductive vias, the metal structure fills openings defined by the trench liner.

What is claimed is:

1. A microelectronic structure, comprising:
a core substrate including one of a glass material or an organic material, and defining a plurality of trenches therein;
electrically conductive vias extending within the trenches, the vias to provide electrical coupling through the core substrate to semiconductor packages to be attached to the core substrate, individual ones of the vias including:
a trench liner adjacent walls of a corresponding one of the plurality of trenches, the trench liner including an electrically conductive polymer material having double carbon bonds; and
a metal structure on the trench liner.

2. The microelectronic structure of claim 1, wherein at least some of the vias are through vias extending across a thickness of the core substrate.

3. The microelectronic structure of claim 1, wherein the polymer material includes single carbon bonds alternating with the double carbon bonds.

4. The microelectronic structure of claim 1, wherein the polymer material has a conjugated backbone.

5. The microelectronic structure of claim 1, wherein the polymer material includes conjugated pi bonds.

6. The microelectronic structure of claim 1, wherein the polymer material further includes at least one of nitrogen, oxygen, sulfur or hydrogen.

7. The microelectronic structure of claim 1, wherein the polymer material is based on one or more monomers including at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT).

8. The microelectronic structure of claim 1, wherein the metal structure includes one or more layers including copper.

9. The microelectronic structure of claim 1, wherein, for individual ones of at least some of the electrically conductive vias, the metal structure fills openings defined by the trench liner.

10. A semiconductor package including:
a microelectronic structure, comprising:
a core substrate including one of a glass material or an organic material, and defining a plurality of trenches therein;
electrically conductive vias extending within the trenches, the vias to provide electrical coupling through the core substrate to semiconductor packages to be attached to the core substrate, individual ones of the vias including:
a trench liner adjacent walls of a corresponding one of the plurality of trenches, the trench liner including an electrically conductive polymer material having double carbon bonds; and
a metal structure on the trench liner; and
microelectronic assemblies disposed on respective top and bottom surface of the core substrate and including dies electrically coupled to corresponding ones of the vias.

11. The semiconductor package of claim 10, wherein at least some of the vias are through vias extending across a thickness of the core substrate.

12. The semiconductor package of claim 10, wherein the polymer material includes single carbon bonds alternating with the double carbon bonds.

13. The semiconductor package of claim 10, wherein the polymer material has a conjugated backbone.

14. The semiconductor package of claim 10, wherein the polymer material includes conjugated pi bonds.

15. The semiconductor package of claim 10, wherein the polymer material further includes at least one of nitrogen, oxygen, sulfur or hydrogen.

16. The semiconductor package of claim 10, wherein the polymer material is based on one or more monomers including at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT).

17. An integrated circuit (IC) device assembly including:
a printed circuit board; and
a plurality of integrated circuit components coupled to the printed circuit board, individual ones of the integrated circuit components including one or more semiconductor packages, individual ones of the semiconductor packages including:
a microelectronic structure, comprising:
a core substrate including one of a glass material or an organic material, and defining a plurality of trenches therein;
electrically conductive vias extending within the trenches, the vias to provide electrical coupling through the core substrate to semiconductor packages to be attached to the core substrate, individual ones of the vias including:
a trench liner adjacent walls of a corresponding one of the plurality of trenches, the trench liner including an electrically conductive polymer material having double carbon bonds; and
a metal structure on the trench liner; and
microelectronic assemblies disposed on respective top and bottom surface of the core substrate and including dies electrically coupled to corresponding ones of the vias.

18. The IC device assembly of claim 17, wherein at least some of the vias are through vias extending across a thickness of the core substrate.

19. The IC device assembly of claim 17, wherein the polymer material including single carbon bonds alternating with the double carbon bonds.

20. A method to form a microelectronic structure of a semiconductor package, the method including:
providing a core substrate including one of a glass material or an organic material;
providing a plurality of trenches extending within the core substrate;
depositing, on walls of individual ones of the trenches, respective trench liners including an electrically conductive polymer material having double carbon bonds; and
providing respective a metal structures on corresponding ones of the trench liners, wherein the respective metal structures and corresponding trench liners thereof together define respective electrically conductive vias to provide electrical coupling through the core substrate to one or more semiconductor packages to be attached to the core substrate.

21. The method of claim 20, wherein depositing the trench liners includes oxidative chemical vapor deposition (oCVD).

22. The method of claim 21, wherein the oCVD is to take place at a pressure between about 100 mTorr and about 500 mTorr.

23. The method of claim 22, wherein the oCVD is to take place at a temperature between room temperature (about 20 to about 22 degree Centigrade) and about 300 degrees Centigrade.

24. The method of claim 21, wherein the oCVD includes using reactants including one or more monomers, and one or more electron acceptor chemicals, wherein the one or more monomers include at least on of carbon, hydrogen, oxygen, sulfur or nitrogen, and wherein the one or more electron acceptor chemicals include a Lewis acid.

25. The method of claim 24, wherein:
the one or more monomers includes at least one of: 3,4-Ethylenedioxythiophene (EDOT), Thiophene, 3,4-Ethylenedithiathiophene (EDTT), Aniline, Pyrrole, Selenophene, 3,4-Dimethoxythiophene (DMOT), 3-Thiophene acetic acid (TAA), 3-Thiophene ethanol (3TE), 1,3-Dihydroisothianaphthene (DHITN), Anthracene, Biphenyl, 3,4-Dimethyl thiophene (DMT), 3-Methyl thiophene (MT), 3,4-Propylene dioxythiophene (ProDOT), 3,4-(2,2-Dimethylpropylenedioxy)thiophene (DMProDOT), 2,2′-Bithiophene (BiT)3,2′: 5′,3″-Terthiophene (TerT), Thieno[3,2-b]thiophene (TT); and
the electron acceptor chemicals include at least one of FeCl₃, SbCl₅, or VOCl₃.
